(19) United States
(12) Patent Application Publication
(10) Pub. No.: US 2026/0216794 A1
(43) Pub. Date: Jul. 30, 2026

(54) COATED TOOL AND CUTTING TOOL

(71) Applicant: KYOCERA CORPORATION, Kyoto-shi, Kyoto (JP)

(72) Inventors: Kenji KUMAI, Satsumasendai-shi, Kagoshima (JP); Hirotoshi ITO, Satsumasendai-shi, Kagoshima (JP); Takumi HASHIMOTO, Satsumasendai-shi, Kagoshima (JP)

(21) Appl. No.: 19/143,895

(22) PCT Filed: Feb. 2, 2024
(86) PCT No.: PCT/JP2024/003393

§ 371 Date: Jun. 27, 2025

(30) Foreign Application Priority Data
Mar. 2, 2023 (JP) 2023-031807

(51) Int. Cl. B23B 27/14; C22C 29/06; C22C 29/08; C23C 16/30; C23C 16/32; C23C 16/34; C23C 16/36; C23C 16/40

(52) U.S. Cl. CPC B23B 27/14; C22C 29/067; C22C 29/08; C23C 16/30; C23C 16/32; C23C 16/34; C23C 16/36; C23C 16/403

(57) ABSTRACT

A coated tool in a non-limiting aspect of the present disclosure includes a base and a coating layer located on a surface of the base. The coating layer includes a Ti-based coating layer. The Ti-based coating layer is in contact with the base. The base includes a crack extending from the surface toward an interior of the base. A part of the Ti-based coating layer is present in the crack.

### CROSS-REFERENCE TO RELATED APPLICATION

The present application claims priority to Japanese Patent Application No. 2023-031807, filed Mar. 2, 2023. The contents of this application are incorporated herein by reference in their entirety.

### TECHNICAL FIELD

The present disclosure relates to a coated tool and a cutting tool.

### BACKGROUND

As a coated tool used in a cutting tool, etc., a coated tool (surface-coated sintered alloy) is known which is described in, for example, Japanese Patent No. 4043145 (Patent Document 1). In the coated tool described in Patent Document 1, a hard coating is coated on a surface of a base material. A diffused element containing layer where an iron group metal and tungsten are diffused is formed in the hard coating.

### SUMMARY

A coated tool in a non-limiting aspect of the present disclosure includes a base and a coating layer located on a surface of the base. The coating layer includes a Ti-based coating layer. The Ti-based coating layer is in contact with the base. The base includes a crack extending from the surface toward an interior of the base. A part of the Ti-based coating layer is present in the crack.

### BRIEF DESCRIPTION OF THE DRAWINGS

FIG. 1 is a perspective view illustrating a coated tool in a non-limiting aspect of the present disclosure;

FIG. 2 is a sectional view perpendicular to a surface of a base in the coated tool illustrated in FIG. 1;

FIG. 3 is an enlarged view of a neighborhood of a boundary between the base and a Ti-based coating layer illustrated in FIG. 2; and

FIG. 4 is a perspective view illustrating a cutting tool in a non-limiting aspect of the present disclosure.

### EMBODIMENT

### <Coated Tool>

A coated tool 1 in a non-limiting aspect of the present disclosure is described in detail below with reference to the drawings. For the convenience of description, the drawings referred to below illustrate, in simplified form, only main members necessary for describing embodiments. Hence, the coated tool 1 may include any arbitrary structural member not illustrated in the drawings referred to. Dimensions of the members in the drawings faithfully represent neither dimensions of actual structural members nor dimensional ratios of these members.

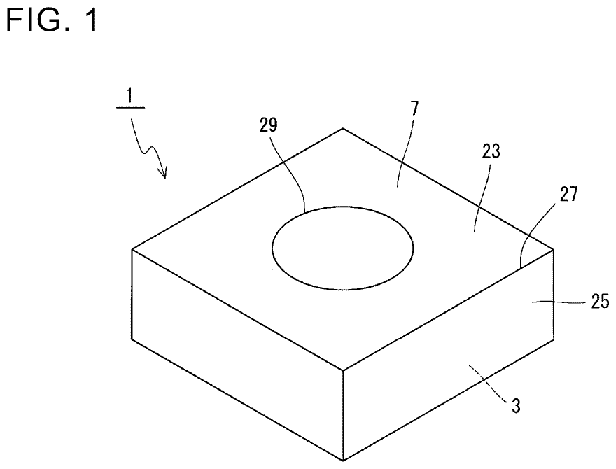

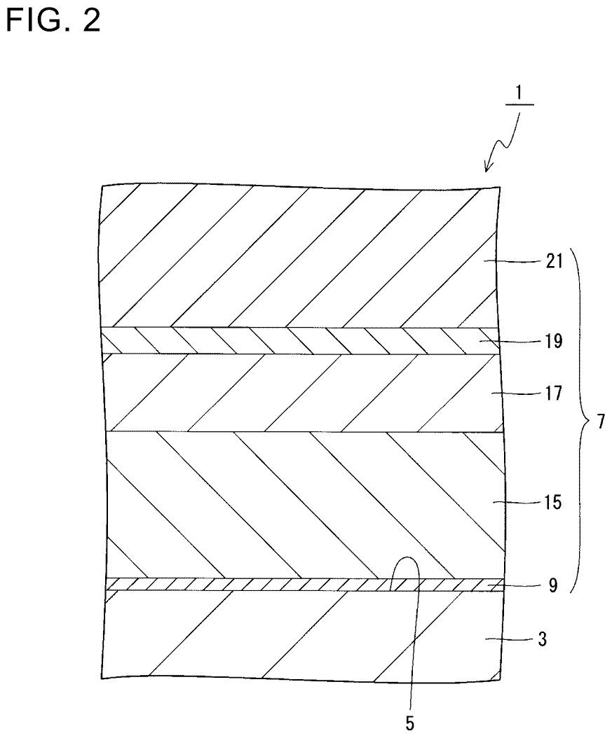

The coated tool 1 may include a base 3 and a coating layer 7 located on a surface 5 of the base 3 as in a non-limiting embodiment illustrated in FIGS. 1 and 2.

The coating layer 7 may include a Ti-based coating layer 9 (titanium-based coating layer). The Ti-based coating layer 9 may be in contact with the base 3. In other words, the Ti-based coating layer 9 may be adjacent to and coated on the base 3. The Ti-based coating layer 9 may also be called an underlayer.

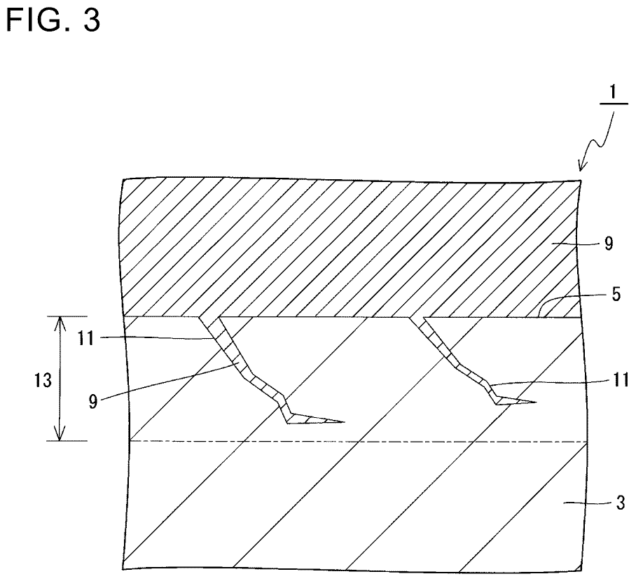

The base 3 may include a crack 11 as in non-limiting embodiment illustrated in FIG. 3. The crack 11 may extend from the surface 5 of the base 3 toward an interior of the base 3. A part of the Ti-based coating layer 9 may be present in the crack 11. In these cases, it is easy to improve adhesive force between the base 3 and the coating layer 7, and it is easy to improve chipping resistance and wear resistance. Therefore, the coated tool 1 has high wear resistance and fracture resistance.

The phrase that the part of the Ti-based coating layer 9 is present in the crack 11 may mean that a portion which is continuous with the Ti-based coating layer 9 and has the same composition as the Ti-based coating layer 9 is located in the interior of the crack 11. The term “having the same composition” may mean that a difference in constituent component between the two is 5% or less. The difference in constituent component may be 3% or less, or may be 1% or less.

For example, a part of the Ti-based coating layer 9 tends to be present in the crack 11 by allowing gas for depositing the Ti-based coating layer 9 to enter the interior of the crack 11 when depositing the Ti-based coating layer 9. Hence, a structure where the part of the Ti-based coating layer 9 is present in the crack 11 may be rephrased as follows: the part of the Ti-based coating layer 9 enters the interior of the crack 11 and is present therein. The crack 11 may be rephrased as cracking. The crack 11 may open into the surface 5 of the base 3.

A confirmation whether the part of the Ti-based coating layer 9 is present in the crack 11 may be performed by, for example, Auger Electron Spectroscopy (AES). Specifically, the confirmation may be performed by cross-sectional observation using EDS (Energy Dispersive X-ray Spectroscopy) included in an electron microscope. Examples of the electron microscope may include Scanning Electron Microscope (SEM) and Transmission Electron Microscope (TEM).

If a concave having a width of 0.05-3 μm and a depth that is more than twice the width is formed from the surface 5 of the base 3 toward the interior of the base 3 in the cross-sectional observation, it can be said that the concave is the crack.

A cross section in the cross-sectional observation may be a cross section perpendicular to the surface 5 of the base 3. An area ratio occupied by the Ti-based coating layer 9 in the interior of the crack 11 may be evaluated in the cross section perpendicular to the surface 5 of the base 3. If the area ratio is 100%, it means that the Ti-based coating layer 9 is present over the whole of the interior of the crack 11. For example, if the area ratio is 30% or more, it could be considered that a part of the Ti-based coating layer 9 was present in the crack 11. An upper limit value of the area ratio is not particularly limited. For example, there is no problem even if the area ratio is 100%.

The base 3 may include a first region 13 that is present from the surface 5 toward the interior. The first region 13 may have a thickness of 0.5-30 μm. The crack 11 may be located in the first region 13.

The base 3 may include a plurality of cracks 11. A part of the Ti-based coating layer 9 may be present in each of the plurality of cracks 11. In these cases, it is easy to improve the adhesive force between the base 3 and the coating layer 7.

The number of the cracks 11 may be measured by the cross-sectional observation using the electron microscope. For example, the cross section perpendicular to the surface 5 of the base 3 may be photographed at 10,000× magnification with the electron microscope, and the number of the cracks 11 present in a range of 8.9 μm×11.8 μm of an obtained electron micrograph may be measured. There may be a plurality of photographic points. For example, there may be five photographic points. The number of the cracks 11 may be 1 to 3 per field of view in the electron micrograph.

In the cross section perpendicular to the surface 5 of the base 3, the crack 11 may include a bent part as in the non-limiting embodiment illustrated in FIG. 3. In this case, it is easy to improve the adhesive force between the base 3 and the coating layer 7. In particular, if being bent so as to approach parallel to the surface 5 of the base 3, it is easier to improve the adhesive force between the base 3 and the coating layer 7.

A length of the crack 11 may be a dimension of the crack 11 in an extending direction (a longitudinal direction) of the crack 11. A width of the crack 11 may be a dimension of the crack 11 in a direction perpendicular to the extending direction (a lateral direction) of the crack 11. The length of the crack 11 may be, for example, 0.5-15 μm. The width of the crack 11 may be, for example, 0.05-3 μm as described above. If the base 3 includes the plurality of cracks 11, the length and width of the cracks 11 may be their respective average values. Their respective average values may be those calculated from two cracks 11.

The base 3 may be a sintered alloy. The sintered alloy may be composed of cemented carbide. In other words, the base 3 may be the cemented carbide. The cemented carbide may include a hard phase and a binder phase. The hard phase in the cemented carbide may include tungsten carbide (WC). The hard phase may include WC as a main component. That is, the cemented carbide may be a WC-based cemented carbide. The term “main component” may mean a component having a larger value of mass % than any other component.

The binder phase in the cemented carbide may include an iron group metal. Examples of the iron group metal may include cobalt (Co) and nickel (Ni). The binder phase in the cemented carbide may include at least one kind selected from the group consisting of Co and Ni. The binder phase in the cemented carbide may include the iron group metal as a main component. The binder phase is servable as a phase that bonds the hard phases adjacent to each other.

The base 3 may be composed of cemented carbide. Hereat, the hard phase may be composed of WC, or may be composed of a cubic crystal structure compound of at least one kind selected from the group consisting of carbides, nitrides, carbon oxides, nitrogen oxides, and solid solutions thereof in Groups 4, 5, and 6 elements in the periodic table, and WC. The binder phase may be composed mainly of Co and/or Ni.

The base 3 may be composed of cemented carbide. Hereat, a nitrogen (N) content in the crack 11 may be 2 mass % or more. In other words, a nitrogen content ratio in a part located at the crack 11 in the Ti-based coating layer 9 may be 2 mass % or more. In this case, it is easy to improve wear resistance and fracture resistance. The nitrogen content in the crack 11 may be 2-30 mass %.

A carbon (C) content in the crack 11 may be 2-30 mass %. In other words, a carbon content ratio in the part located at the crack 11 in the Ti-based coating layer 9 may be 2-30 mass %.

A composition analysis of the crack 11 may be performed using the EDS. The composition analysis may be performed at an acceleration voltage of 20 kV by selecting elements of Ti, C, N, W, and Co in the EDS. The composition analysis of the crack 11 may be performed by cross-sectional observation, and arbitrary five portions may be measured to calculate an average value thereof. If the base 3 is composed of the cemented carbide, the cracks 11 to be measured may be those located at a boundary between WC particles adjacent to each other. This is also true for the case of measuring the number of the cracks 11.

If the base 3 is the sintered alloy, the sintered alloy may be composed of cermet. In other words, the base 3 may be composed of the cermet. The cermet may include a hard phase and a binder phase. The hard phase in the cermet may include, for example, a titanium (Ti) compound. Examples of the Ti compound may include titanium carbonitride (TiCN), titanium carbide (TiC), and titanium nitride (TiN). The hard phase in the cermet may include the Ti compound as a main component. That is, the cermet may be a Ti-based cermet.

The binder phase in the cermet may include an iron group metal. The binder phase in the cermet may include at least one kind selected from the group consisting of Co and Ni. The binder phase in the cermet may include an iron group metal as a main component.

A composition of the base 3 may be measured by, for example, the EDS. A measurement may be performed using the EDS included in the electron microscope.

The Ti-based coating layer 9 may be a single layer or a laminated structure where a plurality of layers are laminated one upon another. Examples of composition of the Ti-based coating layer 9 may include TiN and TiC. For example, if the Ti-based coating layer 9 is the single layer, the Ti-based coating layer 9 may be a TiN layer.

If the Ti-based coating layer 9 is the laminated structure, the Ti-based coating layer 9 may have a structure where a TiN layer and a TiC layer are alternately laminated in three or more layers. A layer closest to the base 3 may be the TiN layer. That is, the Ti-based coating layer 9 may have the laminated structure where the TiN layer and the TiC layer are alternately laminated in at least three layers, and the layer closest to the base 3 in the laminated structure may be the TiN layer. In these cases, it is easy to improve wear resistance and fracture resistance. The number of layers to be laminated may be set to 3 to 8.

The coating layer 7 need not have a specific thickness. For example, an average thickness of the Ti-based coating layer 9 may be set to 0.1-1 μm. The thickness of the Ti-based coating layer 9 is a value obtained by excluding the part being present in the crack 11. If the Ti-based coating layer 9 is the laminated structure, the exemplified thickness of the Ti-based coating layer 9 is a whole thickness. If the Ti-based coating layer 9 is the laminated structure, the individual layers may be identical or different in thickness.

The thickness of the coating layer 7 may be measured by cross-sectional observation using the electron microscope. For example, the thickness may be measured at 10 or more measuring points at an arbitrary position of the Ti-based coating layer 9, and an average value thereof may be calculated. This is also true for other layers described below.

As in the non-limiting embodiment illustrated in FIG. 2, the coating layer 7 may include the Ti-based coating layer 9, a first TiCN layer 15, a second TiCN layer 17, a TiCNO layer 19 (titanium oxycarbonitride layer), and an Al₂O₃ layer 21 (alumina layer) in sequence from the base 3. In this case, the coated tool 1 tends to have a long lifetime.

The first TiCN layer 15 may be a so-called MT (moderate temperature)-TiCN layer. An average thickness of the first TiCN layer 15 may be set to 2-15 μm. In this case, the first TiCN layer 15 has high wear resistance and fracture resistance. A titanium carbonitride crystal included in the first TiCN layer 15 may be a columnar crystal that is narrow and long in a thickness direction of the coating layer 7. The first TiCN layer 15 may be in contact with the Ti-based coating layer 9.

The second TiCN layer 17 may be a so-called HT (high temperature)-TiCN layer. An average thickness of the second TiCN layer 17 may be set to 10-900 nm. The second TiCN layer 17 may be in contact with the first TiCN layer 15.

An average thickness of the TiCNO layer 19 may be set to 200-2000 nm. In this case, hardness of the TiCNO layer 19 is less likely to decrease. Additionally, the Al₂O₃ layer 21 tends to be an αtype crystal structure. The TiCNO layer 19 may be in contact with the second TiCN layer 17.

An average thickness of the Al₂O₃ layer 21 may be set to 1-15 μm. The average thickness of the Al₂O₃ layer 21 may be larger than the average thickness of the TiCNO layer 19. The Al₂O₃ layer 21 may be in contact with the TiCNO layer 19.

The coating layer 7 may be located on the whole or a part of the surface 5 of the base 3. That is, the coating layer 7 may be located on at least the part of the surface 5 of the base 3.

The coating layer 7 may be deposited by Chemical Vapor Deposition (CVD) method. In other words, the coating layer 7 may be a CVD film. Alternatively, the coating layer 7 may be a PVD film deposited by Physical Vapor Deposition (PVD) method.

FIG. 1 illustrates a cutting insert as a non-limiting embodiment of the coated tool 1. The embodiment of the coated tool 1 need not be the cutting insert.

The coated tool 1 may include a first surface 23 (upper surface), a second surface 25 (lateral surface) adjacent to the first surface 23, and a cutting edge 27 located on an intersection of the first surface 23 and the second surface 25.

The first surface 23 may be a rake surface. The whole or a part of the first surface 23 may be the rake surface. For example, a region along the cutting edge 27 in the first surface 23 may be the rake surface.

The second surface 25 may be a flank surface. The whole or a part of the second surface 25 may be the flank surface. For example, a region along the cutting edge 27 in the second surface 25 may be the flank surface.

The cutting edge 27 may be located on the whole or a part of the intersection of the first surface 23 and the second surface 25. The cutting edge 27 is usable for machining a workpiece if a machined product is manufactured using the coated tool 1.

The coated tool 1 may include a through hole 29. The through hole 29 is usable for attaching a screw or clamping member when holding the coated tool 1 in a holder. The through hole 29 may be formed from the first surface 23 to a surface (lower surface) located on a side opposite to the first surface 23. The through hole 29 may also open into these surfaces. There is no problem even if the through hole 29 is configured to open into regions opposed to each other in the second surface 25.

The coated tool 1 may have a quadrangular plate shape. The shape of the coated tool 1 need not be the quadrangular plate shape. For example, the first surface 23 may have a triangular shape, a pentagonal shape, a hexagonal shape, or a circular shape.

The coated tool 1 need not have specific dimensions. For example, a length of one side of the first surface 23 may be set to approximately 3-20 mm. A height from the first surface 23 to the surface (lower surface) on the side opposite to the first surface 23 may be set to approximately 5-20 mm.

### <Method for Manufacturing Coated Tool>

A method for manufacturing a coated tool in a non-limiting aspect of the present disclosure is described below.

A base may be manufactured initially when manufacturing the coated tool. A description is given by exemplifying the case where a base composed of a sintered alloy is manufactured as the base. Firstly, metal powder, carbon powder, etc. may be suitably added to an inorganic powder of carbide, nitride, carbonitride, oxide, etc., with which it is possible to form the base by sintering, and these may be then mixed together to obtain a mixed powder. Subsequently, the mixed powder may be molded into a predetermined tool shape by a well-known molding method, such as press molding, casting molding, extrusion molding, and cold isostatic pressing. The base composed of the sintered alloy may be obtained by sintering an obtained molded body in a vacuum or non-oxidizing atmosphere.

A surface of the obtained base may be subjected to a honing process (polishing process). The honing process may be carried out by blasting process with an air pressure of 0.1-0.3 MPa and a slurry concentration of 5-15 mass %. In this case, it is easy to form a crack extending from the surface of the base toward the interior of the base.

Subsequently, a coating layer may be deposited on the surface of the obtained base by CVD method, thereby obtaining the coated tool. The case where the coating layer includes a Ti-based coating layer, a first TiCN layer (MT-TiCN layer), a second TiCN layer (HT-TiCN layer), a TiCNO layer, and an Al₂O₃ layer in sequence from the base is exemplified to sequentially describe their respective deposition conditions.

If the TiN layer is deposited as the Ti-based coating layer, firstly, a mixed gas composed of 0.5-10 vol % of titanium tetrachloride (TiCl₄) gas, 10-60 vol % of nitrogen (N₂) gas, and the rest that is hydrogen (H₂) gas may be prepared as a reaction gas composition. Then, the mixed gas may be introduced into a chamber to deposit the TiN layer by setting a deposition temperature of 790-940° C. and a pressure of 8-50 kPa.

If a TiC layer is deposited as the Ti-based coating layer, firstly, a mixed gas composed of 0.5-10 vol % of titanium tetrachloride (TiCl₄) gas, 5-30 vol % of methane (CH₄) gas, and the rest that is hydrogen (H₂) gas may be prepared as a reaction gas composition. Then, the mixed gas may be introduced into the chamber to deposit the TiC layer by setting a deposition temperature of 790-940° C. and a pressure of 8-50 kPa.

If the TiN layer and the TiC layer are alternately laminated in at least three layers, the TiN layer deposition and the TiC layer deposition may be alternately repeated.

At this point, a part of the Ti-based coating layer may be allowed to be present in the crack by intentionally allowing the gas for depositing the Ti-based coating layer to enter the interior of the crack.

For example, if the Ti-based coating layer is a single layer, such as the TiN layer, Ti-based coating particles are atomized to facilitate their entry into the interior of the crack by setting a deposition temperature to a temperature as low as 790-820° C. Also, in the case where the Ti-based coating layer is the laminated structure where the TiN layer and the TiC layer are alternately laminated in at least three layers, the Ti-based coating particles are atomized to facilitate their entry into the interior of the crack. However, if the Ti-based coating layer is simply deposited, the gas is less likely to enter the interior of the crack.

The first TiCN layer (MT-TiCN layer) may be deposited as follows. Firstly, a mixed gas composed of 0.5-10 vol % of titanium tetrachloride (TiCl₄) gas, 5-60 vol % of nitrogen (N₂) gas, 0.1-3 vol % of acetonitrile (CH₃CN) gas, and the rest that is hydrogen (H₂) gas may be prepared as a reaction gas composition. Then, the mixed gas may be introduced into the chamber to deposit the first TiCN layer by setting a deposition temperature that is a relatively low temperature of 780-880° C., and a pressure of 5-25 kPa. By increasing a content ratio of the acetonitrile (CH₃CN) gas at a later stage of the deposition than that at an initial stage of the deposition, an average crystal width of titanium carbonitride columnar crystals constituting the first TiCN layer tends to be larger on a side of the surface than a side of the base.

The second TiCN layer (HT-TiCN layer) may be deposited as follows. Firstly, a mixed gas composed of 1-4 vol % of titanium tetrachloride (TiCl₄) gas, 5-20 vol % of nitrogen (N₂) gas, 0.1-10 vol % of methane (CH₄) gas, and the rest that is hydrogen (H₂) gas may be prepared as a reaction gas composition. Then, the mixed gas may be introduced into the chamber to deposit the second TiCN layer by setting a deposition temperature of 900-990° C. and a pressure of 5-40 kPa. The second TiCN layer may be deposited at a higher temperature than the first TiCN layer.

The TiCNO layer may be deposited as follows. Firstly, a mixed gas composed of 3-15 vol % of titanium tetrachloride (TiCl₄) gas, 3-50 vol % of nitrogen (N₂) gas, 0.5-15 vol % of methane (CH₄) gas, 0.5-10 vol % of carbon monoxide (CO) gas, and the rest that is hydrogen (H₂) gas may be prepared as a reaction gas composition. Then, the mixed gas may be introduced into the chamber to deposit the TiCNO layer by setting a deposition temperature of 900-1010° C. and a pressure of 5-40 kPa.

The Al₂O₃ layer may be deposited as follows. Firstly, a mixed gas composed of 3.5-15 vol % of aluminum trichloride (AlCl₃) gas, 0.5-2.5 vol % of hydrogen chloride (HCl) gas, 0.5-5 vol % of carbon dioxide (CO₂) gas, 0-1 vol % of hydrogen sulfide (H₂S) gas, and the rest that is hydrogen (H₂) gas may be prepared as a reaction gas composition. Then, the mixed gas may be introduced into the chamber to deposit the Al₂O₃ layer by setting a deposition temperature of 900-1010° C. and a pressure of 5-20 kPa.

The above manufacturing method is one embodiment of the method for manufacturing the coated tool. Hence, it is needless to say that the coated tool need not be one which is manufactured by the above manufacturing method.

### <Cutting Tool>

A cutting tool 101 in a non-limiting aspect of the present disclosure is described below with reference to the drawings by exemplifying the case of including the coated tool 1.

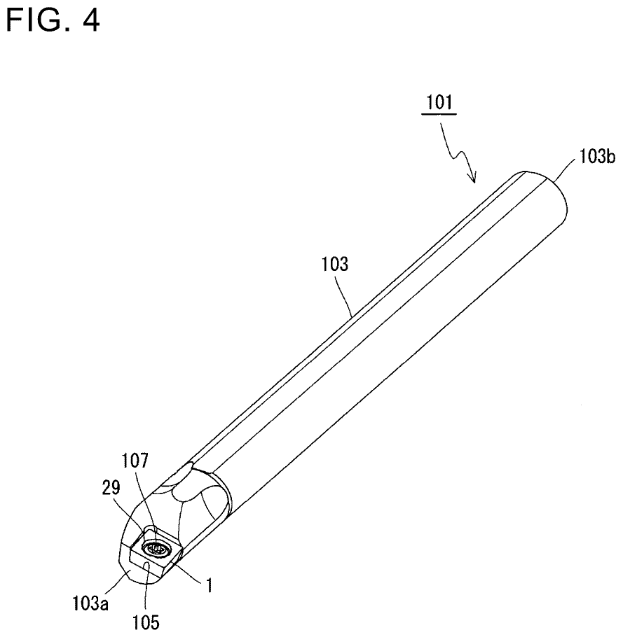

The cutting tool 101 may include a holder 103 and the coated tool 1 as in non-limiting embodiment illustrated in FIG. 4. The holder 103 may extend from a first end 103a toward a second end 103b, and may include a pocket 105 on a side of the first end 103a. The coated tool 1 may be located in the pocket 105. If the cutting tool 101 includes the coated tool 1, it is possible to perform a stable machining because the coated tool 1 has high wear resistance and fracture resistance.

The pocket 105 may be a part that permits attachment of the coated tool 1. The pocket 105 may open into an outer peripheral surface of the holder 103 and an end surface on a side of the first end 103a.

The coated tool 1 may be attached to the pocket 105 so that at least a part of a cutting edge 27 can protrude from the holder 103. The coated tool 1 may also be attached to the pocket 105 by a screw 107. That is, the coated tool 1 may be attached to the pocket 105 by inserting the screw 107 into a through hole 29 of the coated tool 1, and by inserting a front end of the screw 107 into a screw hole formed in the pocket 105 so as to fix the screw 107 to the screw hole. At this time, a lower surface of the coated tool 1 may be directly contacted with the pocket 105, or alternatively, a sheet may be held between the coated tool 1 and the pocket 105.

For example, steel and cast iron are usable as a material of the holder 103. If the material of the holder 103 is steel, the holder 103 has high toughness.

The cutting tool 101 used in a so-called turning process is exemplified in the embodiment illustrated in FIG. 4. Examples of the turning process may include internal machining, external machining, and grooving process. The use of the cutting tool 101 (the coated tool 1) is not limited to the turning process. For example, there is no problem even if the coated tool 1 is used in the cutting tool 101 used in a milling process.

While the coated tool 1 and the cutting tool 101 in the non-limiting aspects of the present disclosure have been exemplified above, the present disclosure is not limited to the above embodiments. Needless to say, it is possible to make any arbitrary one without departing from the scope of the present disclosure.

Although the above non-limiting embodiment has described, for example, the case of applying the coated tool 1 to the cutting tool 101, the coated tool 1 is also applicable to other uses. Examples of other uses may include wear-resistant parts such as sliding parts and metal molds, digging tools, tools such as edged tools, and impact-resistant parts.

The coated tool 1 and the cutting tool 101 may have the following configurations.

(1) The coated tool is one which includes a base and a coating layer located on a surface of the base. The coating layer includes a Ti-based coating layer, and the Ti-based coating layer is in contact with the base. The base includes a crack extending from the surface toward an interior of the base. A part of the Ti-based coating layer is present in the crack.

(2) In the coated tool of the above (1), the base may be a sintered alloy composed of cemented carbide or cermet, each including a hard phase and a binder phase.

(3) In the coated tool of the above (1), the base may be composed of cemented carbide including a hard phase and a binder phase. The hard phase may be composed of tungsten carbide, or composed of a cubic crystal structure compound of at least one kind selected from the group consisting of carbides, nitrides, carbon oxides, nitrogen oxides, and solid solutions thereof in Groups 4, 5, and 6 elements in the periodic table, and tungsten carbide. The binder phase may be composed mainly of cobalt and/or nickel.

(4) In the coated tool of the above (1), the base may be composed of cemented carbide including a hard phase and a binder phase, and a nitrogen content in the crack may be 2 mass % or more.

(5) In the coated tool of the above (4), a carbon content in the crack may be 2-30 mass % or more.

(6) In the coated tool of any one of the above (1) to (5), the Ti-based coating layer 9 may have a laminated structure where a TiN layer and a TiC layer are alternately laminated in at least three layers, and a layer closest to the base in the laminated structure may be the TiN layer.

(7) In the coated tool of any one of the above (1) to (6), the coating layer may include the Ti-based coating layer, a first TiCN layer, a second TiCN layer, a TiCNO layer, and an Al₂O₃ layer in sequence from the base.

(8) A cutting tool can include a holder that extends from a first end toward a second end and includes a pocket on a side of the first end, and the coated tool of any one of the above (1) to (7), which is located in the pocket.

Although the present disclosure is described in detail below by giving Examples, the present disclosure is not limited to the following Examples.

### EXAMPLES

### [Samples Nos. 1 to 5]

### <Manufacturing of Coated Tools>

Firstly, a base was manufactured. Specifically, 7 mass % of a metallic cobalt powder whose mean particle diameter was 1.2 μm, 2 mass % of a titanium carbide powder whose mean particle diameter was 2 μm, 1 mass % of a niobium carbide powder whose mean particle diameter was 2 μm, 3 mass % of tantalum carbide whose mean particle diameter was 1.2 μm, 1 mass % of zirconium carbide whose mean particle diameter was 1.2 μm, and the rest that was a tungsten carbide powder whose mean particle diameter was 1.5 μm were mixed together to obtain a mixed powder. The mean particle diameters of these powders were values measured by micro-track method.

Subsequently, the obtained mixed powder was subjected to press molding into a tool shape (CNMG120408), thereby obtaining a molded body. The obtained molded body was subjected to debinding treatment and then sintering in a non-oxidizing atmosphere, thereby obtaining the base composed of cemented carbide. A sintering temperature was set to 1450° C., and sintering time was set to one hour. An argon atmosphere was employed as the non-oxidizing atmosphere.

A composition of the obtained cemented carbide was measured with an EDS. Specifically, a cross-sectional observation using the EDS included in an SEM was carried out, and the composition was measured under conditions where an average value was obtained by measuring five locations at 5,000-20,000× magnification. As a measuring element, five elements of tungsten carbide, cobalt, titanium, carbon, and nitrogen were selected to carry out the EDS.

The measurement results of the EDS showed that the obtained cemented carbide included the hard phase and the binder phase. More specifically, the obtained cemented carbide included the hard phase composed of WC, and the binder phase composed mainly of Co.

A surface of the obtained base was subjected to a honing process (polishing process). The honing process was carried out by blasting process with an air pressure of 0.1-0.3 MPa and a slurry concentration of 5-15 mass %.

A cross-sectional observation of the base after subjected to the honing process was performed by the SEM. The result showed that the base included a plurality of cracks.

Subsequently, a coating layer was deposited on the surface of the obtained base by CVD method, thereby obtaining a coated tool of each of samples presented in Table 1. In the samples presented in Table 1, a Ti-based coating layer was firstly deposited on the surface of the base, and a first TiCN layer (MT-TiCN layer), a second TiCN layer (HT-TiCN layer), a TiCNO layer, and an Al₂O₃ layer were deposited in this order on the Ti-based coating layer. Individual deposition conditions are as follows.

### (Deposition Conditions of Ti-Based Coating Layer)

If depositing a single layer of a TiN layer, firstly, a mixed gas composed of 1 vol % of titanium tetrachloride (TiCl₄) gas, 38 vol % of nitrogen (N₂) gas, and the rest that was hydrogen (H₂) gas was prepared as a reaction gas composition. Then, the mixed gas was introduced into a chamber, and a deposition temperature, pressure, and deposition time were set to conditions presented in Table 1.

If alternately laminating a TiN layer and a TiC layer in at least three layers, firstly, a mixed gas for the TiC layer was prepared. Specifically, a mixed gas composed of 2 vol % of titanium tetrachloride (TiCl₄) gas, 10 vol % of methane (CH₄) gas, and the rest that was hydrogen (H₂) gas was prepared as a reaction gas composition for the TiC layer. The same mixed gas as in the case of depositing the single layer of the TiN layer was also used as a mixed gas for the TiN layer. These mixed gases were alternately introduced into the chamber so as to obtain a composition presented in Table 1, and a deposition temperature, pressure, and deposition time were set to conditions presented in Table 1.

In the composition presented in Table 1, for example, “TiN—TiC—TiN” indicates that the TiN layer, the TiC layer, and the TiN layer were laminated in sequence from the base. The TiN layer and the TiC layer were deposited at the same deposition temperature and pressure. The deposition time presented in Table 1 is a total of deposition time for the individual layers. The deposition time for each of the layers can be calculated from the following equation: (Deposition time)/(Number of layers).

### (Deposition Conditions of First TiCN Layer (MT-TiCN Layer))

Firstly, a mixed gas composed of 4 vol % of titanium tetrachloride (TiCl₄) gas, 23 vol % of nitrogen (N₂) gas, 0.4 vol % of acetonitrile (CH₃CN) gas, and the rest that was hydrogen (H₂) gas was prepared as a reaction gas composition. Then, the mixed gas was introduced into the chamber. A deposition temperature was set to 850° C., and a pressure was set to 9 kPa. Deposition time was set to 400 minutes.

### (Deposition Conditions of Second TiCN Layer (HT-TiCN Layer))

Firstly, a mixed gas composed of 4 vol % of titanium tetrachloride (TiCl₄) gas, 20 vol % of nitrogen (N₂) gas, 8 vol % of methane (CH₄) gas, and the rest that was hydrogen (H₂) gas was prepared as a reaction gas composition. Then, the mixed gas was introduced into the chamber. A deposition temperature was set to 950° C., and a pressure was set to 13 kPa. Deposition time was set to 80 minutes.

### (Deposition Conditions of TiCNO Layer)

Firstly, a mixed gas composed of 4 vol % of titanium tetrachloride (TiCl₄) gas, 20 vol % of nitrogen (N₂) gas, 8 vol % of methane (CH₄) gas, 2 vol % of carbon monoxide (CO) gas, and the rest that was hydrogen (H₂) gas was prepared as a reaction gas composition. Then, the mixed gas was introduced into the chamber. A deposition temperature was set to 950° C., and a pressure was set to 10 kPa. Deposition time was set to 30 minutes.

(Deposition Conditions of Al₂O₃ Layer)

Firstly, a mixed gas composed of 3.7 vol % of aluminum trichloride (AlCl₃) gas, 0.7 vol % of hydrogen chloride (HCl) gas, 4.3 vol % of carbon dioxide (CO₂) gas, 0.3 vol % of hydrogen sulfide (H₂S) gas, and the rest that was hydrogen (H₂) gas was prepared as a reaction gas composition. Then, the mixed gas was introduced into the chamber. A deposition temperature was set to 950° C., and a pressure was set to 7.5 kPa. Deposition time was set to 380 minutes.

A confirmation whether a part of the Ti-based coating layer was present in the crack was performed on the obtained coated tools according to the method exemplified above. Specifically, the conformation was performed by cross-sectional observation using an EDS included in an SEM. Measurement results are presented in a column of “Presence of Ti-based coating layer in crack.” In this column, “presence” indicates that the part of the Ti-based coating layer was present in the crack, and “absence” indicates that the part of the Ti-based coating layer was not present in the crack. Additionally, a composition analysis of the crack was performed according to the method exemplified above. Measurement results are presented in a column of “composition of crack” in Table 1.

### <Evaluation>

A machining test was conducted on the obtained coated tools under the following conditions:
Machining Type: Turning
Cutting Speed: 300 m/min
Feed: 0.3 mm/rev
Depth of Cut: 2 mm
Workpiece: SCM435 $200 round rod
Machining State: WET

The test results are presented in Table 1. The term “machining time until occurrence of chipping (min)” in Table 1 indicates the time until the cutting edge fractures. The term “machining time until amount of wear reaches 0.2 mm (min)” indicates the time until the amount of wear reaches 0.2 mm on the flank surface of the cutting edge.

TABLE 1

| | Deposition conditions of | | | | | | | Presence of | Machining | Machining |
|---|---|---|---|---|---|---|---|---|---|---|
| | Ti-based coating layer | | | | | | | Ti-based | time until | time until |
| | | Deposition | | Deposition | Composition of | | | coating | occurrence | amount of |
| Sample | | temperature | Pressure | time | crack(mass %) | | | layer in | of chipping | wear reaches |
| No. | Composition | (° C.) | (kPa) | (min) | C | N | Others | crack | (min) | 0.2 mm (min) |
| 1 | TiN | 800 | 16 | 180 | 4.3 | 8.5 | 87.2 | Presence | 28 | 24 |
| 2 | TiN—TiC—TiN | 850 | 16 | 180 | 3.3 | 4.2 | 92.5 | Presence | 30 | 24 |
| 3 | TiN—TiC—TiN—TiC | 850 | 16 | 180 | 4.6 | 6.2 | 89.2 | Presence | 32 | 24 |
| 4 | TiN | 850 | 16 | 180 | 5.5 | 0.7 | 65.8 | Absence | 21 | 24 |
| 5 | TiN | 900 | 16 | 180 | 5.9 | 0.5 | 69.2 | Absence | 21 | 24 |

The results showed that Samples Nos. 1 to 3 had higher wear resistance and fracture resistance than Samples Nos. 4 and 5.

### DESCRIPTION OF THE REFERENCE NUMERAL

1 coated tool
3 base
5 surface
7 coating layer
9 Ti-based coating layer
11 crack
13 first region
15 first TiCN layer
17 second TiCN layer
19 TiCNO layer
21 Al₂O₃ layer
23 first surface (upper surface)
25 second surface (lateral surface)
27 cutting edge
29 through hole
101 cutting tool
103 holder
103a first end
103b second end
105 pocket
107 screw

1. A coated tool, comprising:
a base; and
a coating layer located on a surface of the base, wherein
the coating layer comprises a Ti-based coating layer,
the T-based coating layer is in contact with the base,
the base comprises a crack extending from the surface toward an interior of the base, and
a part of the Ti-based coating layer is present in the crack.

2. The coated tool according to claim 1, wherein the base is a sintered alloy comprising cemented carbide or cermet, each comprising a hard phase and a binder phase.

3. The coated tool according to claim 1, wherein
the base comprises cemented carbide comprising a hard phase and a binder phase,
the hard phase comprises a tungsten carbide, or comprises a cubic crystal structure compound of at least one kind selected from the group consisting of carbides, nitrides, carbon oxides, nitrogen oxides, and solid solutions thereof in Groups 4, 5, and 6 elements in the periodic table, and tungsten carbide, and
the binder phase comprises mainly of cobalt and/or nickel.

4. The coated tool according to claim 1, wherein
the base comprises cemented carbide comprising a hard phase and a binder phase, and
a nitrogen content in the crack is 2 mass % or more.

5. The coated tool according to claim 4, wherein a carbon content in the crack is 2-30 mass %.

6. The coated tool according to claim 1, wherein
the Ti-based coating layer has a laminated structure where a TiN layer and a TiC layer are alternately laminated in at least three layers, and
a layer closest to the base in the laminated structure is the TiN layer.

7. The coated tool according to claim 1, wherein the coating layer comprises the Ti-based coating layer, a first TiCN layer, a second TiCN layer, a TiCNO layer, and an Al₂O₃ layer in sequence from the base.

8. A cutting tool, comprising:
a holder extending from a first end toward a second end and comprising a pocket on a side of the first end; and
the coated tool according to claim 1, the coated tool being located in the pocket.
